(19) United States
(12) Patent Application Publication
(10) Pub. No.: US 2025/0336876 A1
(43) Pub. Date: Oct. 30, 2025

(54) ELECTRONIC DEVICE WITH NICKEL TUNGSTEN BOTTOM PLATING

(71) Applicant: Texas Instruments Incorporated, Dallas, TX (US)

(72) Inventors: Nazila Dadvand, Santa Clara, CA (US); Huo Yun Duan, Chengdu (CN); Xuan Mo Li, Santa Clara, CA (US)

(21) Appl. No.: 18/646,357

(22) Filed: Apr. 25, 2024

(51) Int. Cl. H01L 23/00

(52) U.S. Cl. CPC H01L 24/32; H01L 24/27; H01L 24/29; H01L 24/48; H01L 24/95; H01L 2224/27462; H01L 2224/29155; H01L 2224/29184; H01L 2224/29211; H01L 2224/32257; H01L 2224/48245; H01L 2224/4845; H01L 2224/95; H01L 2924/3512

(57) ABSTRACT

An electronic device includes a package structure and a conductive lead with a first surface having a first plated layer including nickel tungsten and a second plated layer including tin on the first plated layer. A method includes forming a first plated layer on a first surface of a conductive lead exposed along a bottom side of a molded structure in a panel array, performing a second plating process that forms a second plated layer including tin on the first plated layer, and performing a package separation process that separates an electronic device from the panel array.

### BACKGROUND

Plated coatings on electronic device leads can help improve board level reliability (BLR) performance when the device is soldered to a circuit board by mitigating corrosion or degradation of the conductive metal of the lead bottom or sidewall. Lead plating solutions can improve performance and reliability compared with bare copper surfaces, and lead surface plating can be done before or after electronic device molding operations. Pre-plating lead frames before packaging operations can provide BLR improvement, but this approach significantly increases the cost of the lead frame panel and lengthens the lead frame fabrication cycle time. Moreover, pre-plated lead frames may not be able to accommodate larger device package sizes.

### SUMMARY

In one aspect, an electronic device includes a package structure and a conductive lead partially enclosed by the package structure. The conductive lead includes a first plated layer on a portion of the conductive lead, the first plated layer including nickel tungsten and a second plated layer on the first plated layer, the second plated layer including tin, and the second plated layer exposed outside the package structure.

In another aspect, a system includes a circuit board having a conductive feature, an electronic device, including a package structure having a bottom side, a conductive lead partially enclosed by the package structure and soldered to the conductive feature of the circuit board, the conductive lead including copper, a first plated layer on a portion of the conductive lead, the first plated layer including nickel tungsten, and a second plated layer on the first plated layer. The second plated layer includes tin and is exposed outside the package structure. The system includes solder that connects the second plated layer to the conductive feature of the circuit board.

In a further aspect, a method of fabricating an electronic device includes performing a first plating process that forms a first plated layer including nickel tungsten on a first surface of a conductive lead exposed along a bottom side of a molded structure in a panel array of prospective electronic devices, performing a second plating process that forms a second plated layer including tin on the first plated layer, performing a package separation process that separates an electronic device from the panel array, with the second plated layer exposed along the bottom side of a respective package structure and exposes a second surface of the conductive lead along a further side of the package structure.

### BRIEF DESCRIPTION OF THE DRAWINGS

FIG. 1 is a sectional side elevation view of an electronic device.

FIG. 1A is a bottom view of the electronic device of FIG. 1.

FIG. 1B is a partial sectional side elevation view of a lead of the electronic device of FIGS. 1 and 1A.

FIG. 2 is a flow diagram of a method of fabricating an electronic device.

FIGS. 3-8 are partial sectional side elevation views of the electronic device of FIGS. 1-1B undergoing fabrication processing according to the method of FIG. 2.

FIG. 9 is a partial sectional side elevation view of a lead of a QFN electronic device with a nickel-palladium-gold (NiPdAu) plated lead bottom side finish soldered to a circuit board.

FIG. 10 is a partial sectional side elevation view of a lead of a QFN electronic device with bottom matte tin (Sn) plated lead finish soldered to a circuit board.

FIG. 11 is a partial sectional side elevation view of a lead of a QFN electronic device with a bilayer nickel-tungsten (NiW) and matte tin plated lead bottom side finish soldered to a circuit board.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”.

Unless otherwise stated, “about,” “approximately,” or “substantially” preceding a value means +/−10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc., may be referred to herein as first, second, third, etc., such as first and second terminals, first, second, and third, wells, etc., for ease of description in connection with a particular drawing, where such are not to be construed as limiting with respect to the claims. Various disclosed structures and methods of the present disclosure may be beneficially applied to an electronic apparatus such as an integrated circuit and manufacturing electronic devices. While such examples may be expected to provide various improvements, no particular result is a requirement of the present disclosure unless explicitly recited in a particular claim.

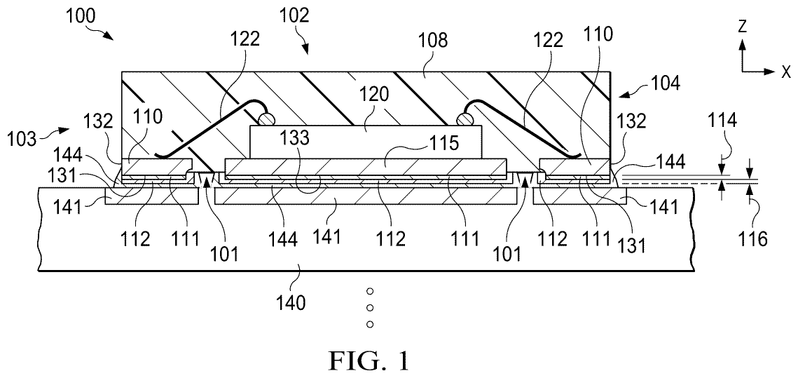

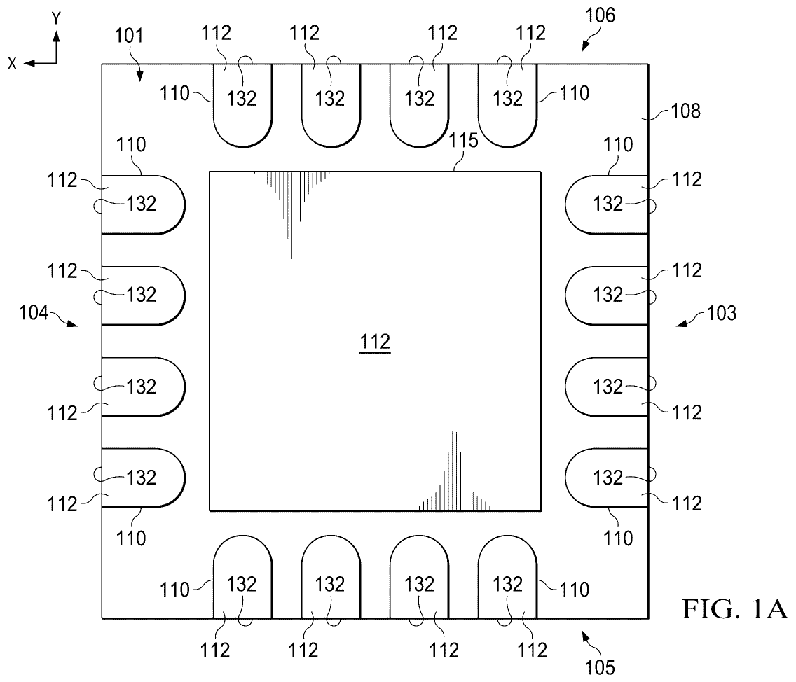

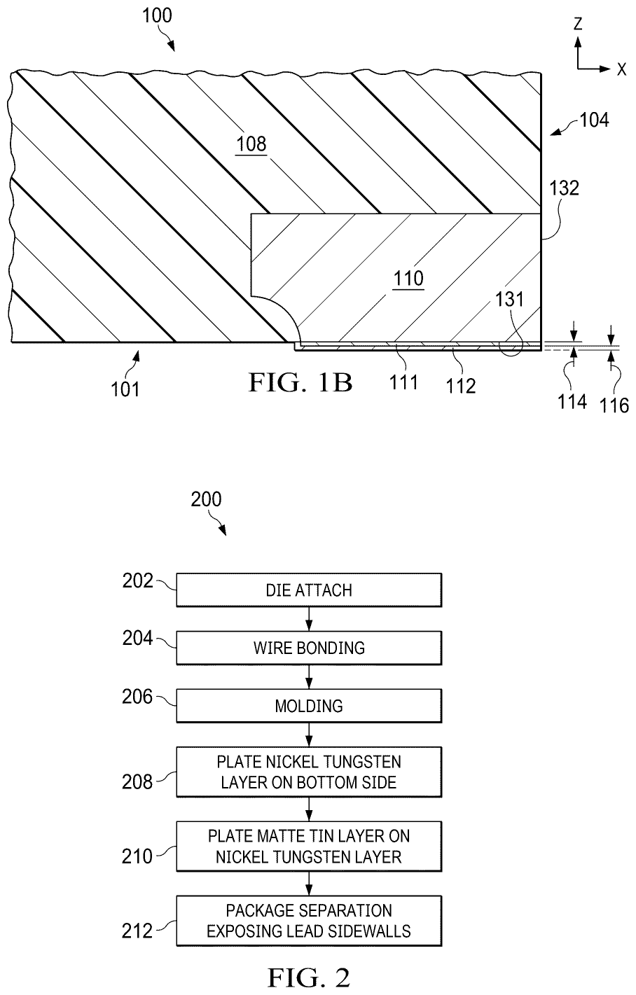

Referring initially to FIGS. 1-1B, FIG. 1 shows an electronic device 100 installed on a system circuit board, FIG. 1A shows a bottom view of the electronic device 100, and FIG. 1B shows a partial view of a conductive lead 110 of the electronic device 100. The electronic device 100 is illustrated in an example position in a three-dimensional space with respective first, second, and third mutually orthogonal directions X, Y, and Z. As best shown in FIG. 1, the electronic device 100 includes opposite first and second (e.g., bottom and top) sides 101 and 102 that are spaced apart from one another along the third direction Z. The electronic device 100 also includes third and fourth sides 103 and 104 spaced apart from one another along the first direction Y, and fifth and sixth sides 105 and 106 (FIG. 1A) that are spaced apart from one another along the second direction Y. The electronic device 100 has a molded package structure 108 that includes the sides 101-106. In the illustrated example, the bottom and top sides 101 and 102 are generally planar and extend in respective X-Y planes of the first and second directions X and Y.

The electronic device 100 includes conductive leads 110 along the lateral sides 103-106 to form a quad flat no-lead (QFN) package structure. In another implementation the device has conductive leads on two opposite sides to provide a dual flat no-lead (DFN) package structure (not shown). The conductive leads 110 are partially enclosed by the package structure 108 and the conductive leads 110 include copper (Cu). As best shown in FIG. 1B, the individual conductive leads 110 have a first (e.g., bottom) surface 131 and a second (e.g., sidewall) surface 132. In one example, the leads 110 are or include copper and the second surface 132 is an unplated copper surface exposed outside the package structure 108 along a respective one of the lateral sides 103-106 before soldering.

As best shown in FIGS. 1 and 1B, a first plated layer 111 extends on a portion of each of the conductive leads 110. In the illustrated example, the first plated layer 111 extends along the first surface 131 of the conductive lead 110, the first plated layer 111 includes nickel tungsten (NiW). A second plated layer 112 extends on the first plated layer 111 and is exposed outside the package structure 108 before soldering. The second plated layer 112 includes tin (Sn). The conductive leads on the other lateral sides 103-106 of the example QFN electronic device 100 are similarly constructed including instances of the first and second plated layers 111 and 112. As shown in FIGS. 1 and 1A, the electronic device 100 also includes a die attach pad 115 that is or includes copper. In other examples, the die attach pad can be omitted or covered by the package structure 108 along the bottom or first side 101. The die attach pad 115 has a first plated layer 111 that includes nickel tungsten on a bottom surface 133 of the die attach pad 115, and a second plated layer 112 that includes tin on the first plated layer 111.

In one example, the instances of the first plated layer 111 on the leads 110 and on the die attach pad 115 each have a thickness 114 (FIG. 1) that is 0.5 μm or more and 1.5 μm or less. In one implementation, the thickness 114 of the first plated layer 111 is approximately 1.0 μm. In these or other examples, the second plated layer 112 has a thickness 116 that is 22.0 μm or less. In one implementation, the thickness 116 of the second plated layer 112 is 3.0 μm or more and 22.0 μm or less. Lower thicknesses below 3.0 μm can inhibit diffusion barrier performance, while larger thicknesses above 22 μm can mitigate electrical conductivity. In these or another example, the second plated layer 112 includes matte tin. In another implementation, the second plated layer 112 has a thickness 116 that is larger, such as approximately 12 μm in combination with a thickness 114 of the first plated layer 111 of approximately 1 μm. The plated layers 111 facilitate corrosion resistance prior to soldering the electronic device 100 onto a circuit board and serve to help create good solder joints to a host system, for example, by providing a diffusion barrier to mitigate copper or other metal diffusion during and after soldering operations and the associated formation of inter-metallic compounds (IMCs) in a solder joint. The bilayer plated structure including the first plated layer 111 and the second plated layer 112 along the bottom sides of the conductive leads 110 and the die attach pad 115 also mitigate cracks and enhance reliability of the electronic device 100 during operation in the host system.

The electronic device 100 has a semiconductor die 120 enclosed by the package structure 108. The semiconductor die 120 has conductive bond pads electrically connected to respective leads 110 by bond wires 122 and includes one or more circuit components (e.g., transistors, diodes, resistors, etc.) formed on or in a semiconductor layer of the semiconductor die 120. The semiconductor die 120 can also include a single or multilevel metallization structure with conductive metal interconnections to the component or components of the semiconductor layer, where one or more further components (e.g., inductors, transformers, resistors, capacitors, etc.) can be formed in whole or in part in the metallization structure. One or more of the conductive leads 110 are electrically coupled to a circuit or component of the semiconductor die 120, for example, by a respective bond wire 122 to provide external connectivity for a circuit of the electronic device 100 to a host system including a circuit board 140 as shown in FIG. 1. In another example, the semiconductor die 120 can be flip chip attached to a lead frame that initially includes the conductive leads 110, and the bond wires 122 can be omitted.

The circuit board 140 has conductive features 141, such as metal landing pads and/or traces. The conductive leads 110 of the electronic device 100 are electrically and mechanically attached to respective conductive features 141 of the circuit board 140 by solder 144 that connects the second plated layer 112 to the conductive feature 141 of the circuit board 140. The solder joints in one example includes solder 144 extending between the corresponding circuit board conductive features 141 and at least a portion of the second plated layer 112 of the conductive leads 110 and of the die attach pad 115. The exposed second surface is 132 of the conductive leads 110 outside the package structure 108 facilitates solder wetting. Portions of the solder 144 in this example also extend along at least a portion of the second surfaces 132 along the sidewalls of the conductive leads 110. The extension of the solder 144 along at least portions of the sidewalls of the conductive leads 110 facilitates optical inspection of the solder joints during manufacturing of the host system including mounting an attachment of the electronic device 100 to the circuit board 140.

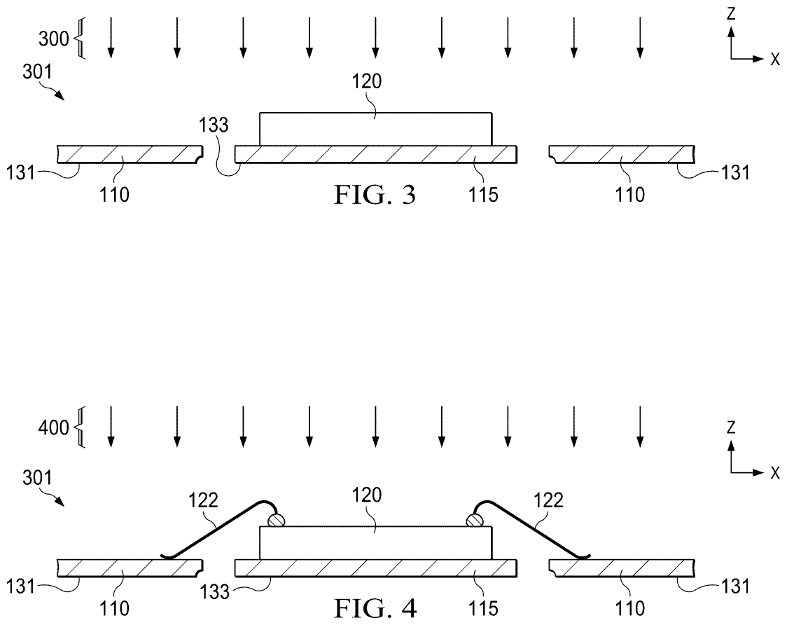

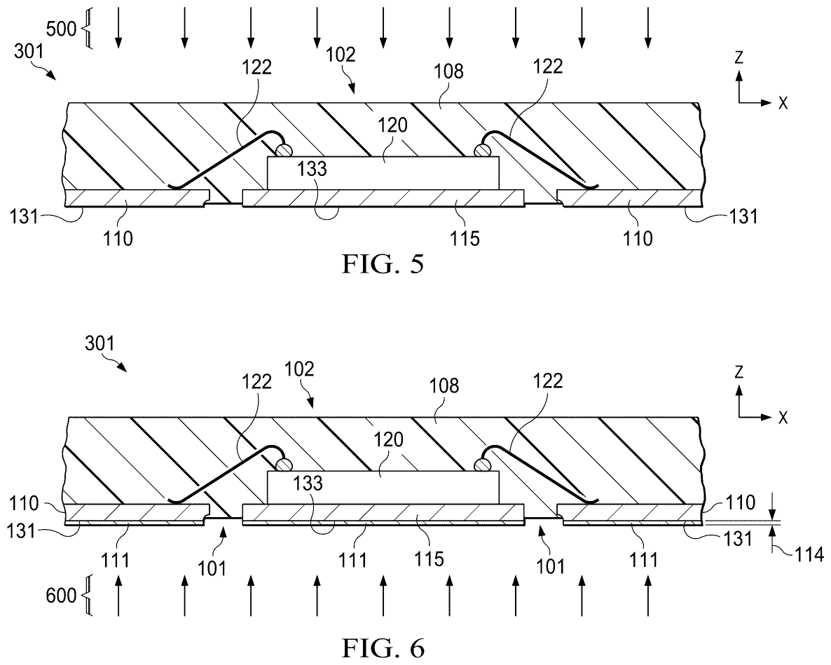

Referring also to FIGS. 2-8, FIG. 2 shows a method 200 of fabricating an electronic device and FIGS. 3-8 show the electronic device 100 of FIGS. 1-1B undergoing fabrication processing according to the method 200. The method 200 includes die attach processing at 202. FIG. 3 shows one example, in which a die attach process 300 is performed that attaches the semiconductor die 120 to the die attach pad 115 of a starting lead frame 301 that also includes the prospective leads 110. The starting lead frame 301 in one example is or includes copper with unplated outer surfaces to minimize lead frame manufacturing cost and reduce lead frame development time. The die attach pad 115 has a lower surface 133 and the leads 110 have lower surfaces 131 as shown in FIG. 3.

In one example, the starting lead frame has multiple prospective device sections or unit areas arranged in rows and columns of a panel array of prospective electronic devices 100, and the die attach process 300 includes concurrent or sequential placement of multiple dies 120 to respective die attach pads 114 of the panel array 301. In one example, the die attach process 300 uses automated pick and place equipment (not shown) to attach a semiconductor die 120 in each unit area of the panel array structure. The die attachment in one example can include dispensing, printing, silk screening, or other form of providing die attach adhesive (not shown) in each unit area of the panel array structure, followed by pick and place attachment of individual semiconductor dies 120 in each unit area. In another example, flip chip die attachment processing is performed, including silk screening or otherwise providing solder paste along selected portions of the starting lead frame 301 and placement of individual semiconductor dies 120 with conductive bond pads thereof engaging the solder paste for subsequent solder reflow processing.

The method 200 continues at 204 with electrical coupling including coupling one or more conductive terminals (e.g., bond pads) of the die 120 to respective conductive leads 110, as well as any die-to-die connections required for a given electronic device design (e.g., die-to-die connections for a multiple chip module or MCM device, not shown). FIG. 4 shows one example, in which a wire bonding process 400 is performed that forms bond wires 122 between respective conductive bond pads of the semiconductor die 120 and associated ones of the conductive leads 110 of the starting lead frame in the panel array 301. In another example (not shown), the electrical connection processing at 204 can include thermal heating to reflow the solder paste to form electrical connections between semiconductor die bond pads and leads or other conductive metal structures of the starting lead frame 301, such as where the semiconductor die 120 is flip chip attached in each unit area of the panel array structure.

The method 200 also includes performing a molding process at 206 that forms a molded package structure 108 that encloses the semiconductor die 120 and the bond wires 122 in each unit area of the panel array structure. FIG. 5 shows one example, in which a molding process 500 is performed that forms the molded package structure 108 that encloses the semiconductor die 120 and the bond wires 122. In one example, a single cavity mold is used for the entire panel array, and the molded package structure 108 extends across all rows and columns of the panel array structure. In another implementation, shared cavities extend along rows or columns of the panel array structure. In yet another example, the individual mold cavities can be used for each unit area of the panel array structure.

The method 200 continues at 208 in FIG. 2, where a first plating process is performed after the molding operations at 206 (post mold plating). The first plating process at 208 forms nickel tungsten on exposed bottom surfaces of the lead frame panel array. FIG. 6 shows one example, in which a first electroplating process 600 is performed that deposits nickel tungsten on the bottom side of the panel array 301 that is exposed outside the molded package structure 108. The process 600 in one example forms the nickel tungsten first plated layer 111 on the bottom surfaces 131 of the conductive leads 110 and on the bottom surface 133 of the die attach pad 115 in each unit area of the panel array structure. In one example, the first plating process 600 forms the first plated layer 111 on the leads 110 and on the die attach pad 115 to a thickness 114 that is 0.5 μm or more and 1.5 μm or less. In one implementation, the first plating process 600 forms the first plated layer 111 to a thickness 114 of approximately 1.0 μm. In one example, the nickel tungsten plating at 208 is performed using a steel belt with hangers that support the lead frame panel array 301 during electroplating, and the first plating process 600 can be preceded by a descaling activation or other cleaning step that cleans the steel belt to remove remnant nickel tungsten created by plating of a previous lead frame panel array, for example, using a nickel tungsten stripping agent.

The method 200 continues at 210 in FIG. 2 with forming the second plated layer 112 on the first plated layer 111. FIG. 7 shows one example, in which a second plating process 700 is performed that forms the second plated layer 112 including tin (Sn) on the exposed surfaces of the first plated layer 111 of the conductive leads 110 exposed outside the bottom side 101 of the molded structure 108 in the panel array 301. The second plating process 700 also forms the second plated layer 112 including tin on the first plated layer 111 along the bottom of the die attach pad 115. In one implementation, the second plating process 700 is an electroplating process that forms the second plated layer 112 including tin on first plated layer 111 of the conductive leads 110 and forms the second plated layer 112 including tin on the first plated layer 111 along the lower or bottom of the die attach pad 115. In one example, the second plated layer 112 is matt tin plating with a nominal thickness 116 of 22.0 μm or less. In one implementation, the thickness 116 of the second plated layer 112 is 3.0 μm or more and 22.0 μm or less. In another example, the thickness 116 can be approximately 12 μm, for example, in combination with a thickness 114 of the first plated layer 111 of approximately 1 μm. In these or another example, the second plated layer 112 includes matte tin, for example, by electroplating in electrolytes without the addition of brighteners to provide a dull tin appearance with low level of internal stresses in matte tin with low whiskers suitable for use in electronic device manufacturing.

The method 200 continues at 212 in FIG. 2 with package separation. FIG. 8 shows one example, in which a package separation process 800 is performed that separates an electronic device 100 from the panel array 301, for example, by saw cutting, laser cutting, or other suitable processing along lines 802. The separation process 800 separates the individual semiconductor device 100 with the tin-plated surface 131 of the conductive lead 110 exposed along the bottom side 101 of each respective package structure 108. The package separation process 800 creates and exposes the second surface 132 of the illustrated conductive leads 110 along the lateral sides 103-106 of the package structure 108. In the illustrated example, the exposed second surface 132 extends generally orthogonal to the bottom first side 101 of the separated package structure 108 (e.g., in an X-Y plane of the first and second directions X and Y in the illustrated orientation).

The illustrated examples provide the cost benefits associated with bare copper lead frames in combination with post mold plating of the first and second plated layers 111 and 112 respectively including nickel tungsten and matte tin. The plated layers 111 and 112 provide advantages with respect to solderability and reduction of cracks in solder joints created during soldering of the packaged electronic device 100 to a host printed circuit board.

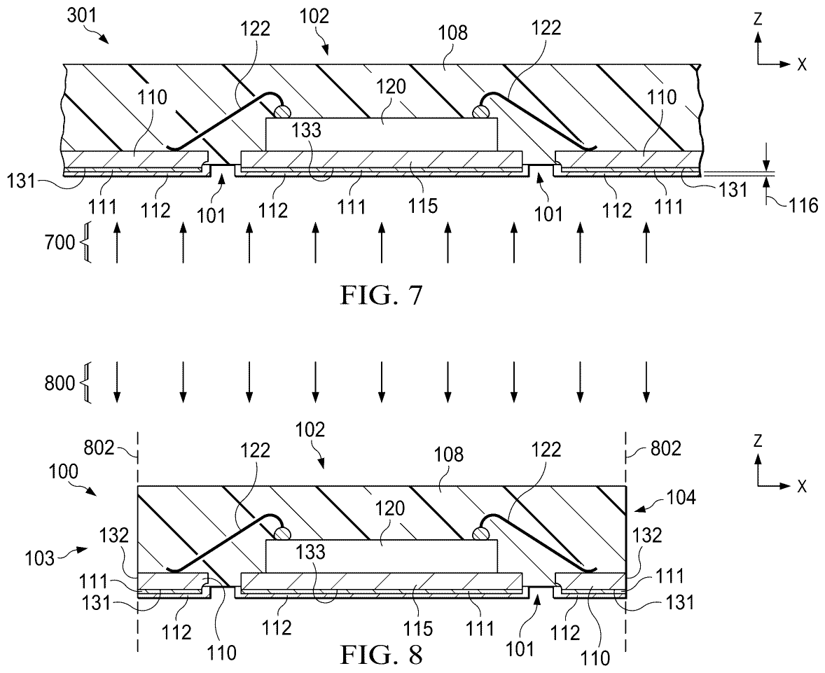

Referring also to FIGS. 9-11, FIG. 9 shows a QFN device 900 with a package structure 908 and a partially exposed conductive copper lead 910 created from a pre-plated copper starting lead frame with a nickel-palladium-gold (NiPdAu) plated lead bottom side finish 901 soldered to a conductive feature 940 of a circuit board by solder 944. This example shows significant solder joint cracking particularly along the bottom side. In addition, the QFN device 900 also exhibits high manufacturing cost, particularly with respect to the pre-plated starting lead frame used in manufacturing the electronic device 900.

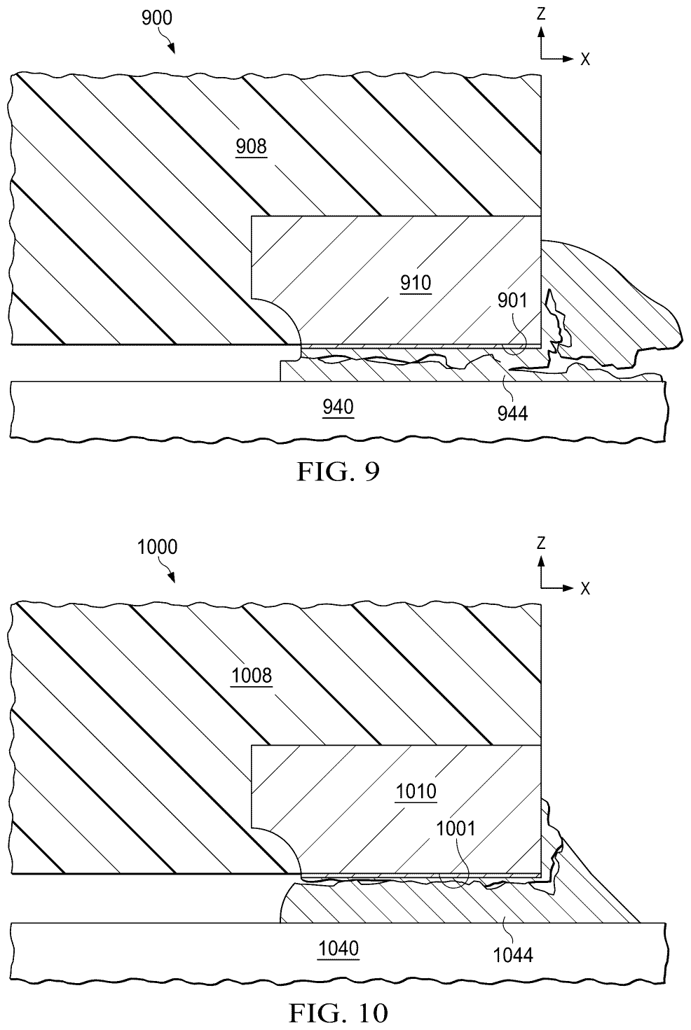

FIG. 10 shows another electronic device 1000 with a package structure 1008 and a partially exposed conductive copper lead 1010 created from a bare copper starting lead frame with a 10 μm thick post mold matte tin plated lead bottom and sidewall finish 1001 soldered to a conductive feature 1040 of a circuit board by solder 1044. This example also exhibits significant solder joint cracking along the bottom and sidewalls of the leads 1010.

The examples of FIGS. 9 and 10 suffer from low board level reliability in view of the significant risk of solder joint cracking when installed on a circuit board. In addition, the board level reliability problems of these examples is worsened as package sizes increase and lead pitch distances are reduced. Even though the post molding plated matte tin allows cost savings with respect to use of a bare copper starting lead frame panel array, the 10 μm thick matte tin plating 1001 of the electronic device 1000 in FIG. 10 suffers from high tin burr rejections for large package sizes and small lead pitch dimensions.

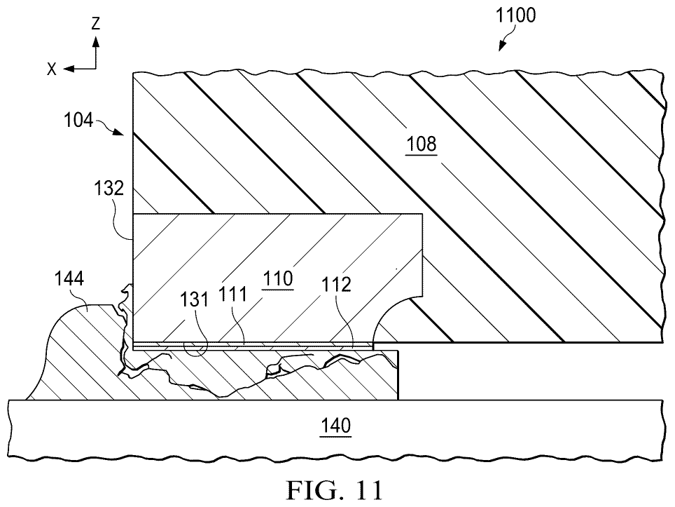

FIG. 11 shows an example portion of an electronic device 1100 having starting copper conductive leads 110 with an example implementation of the nickel tungsten first plated layer 111 (e.g., approximately 1 μm thick) and the matte tin second plated layer 112 (e.g., 3-22 μm thick) as described above, soldered to a conductive feature of a circuit board 140 using solder 144 that partially extends along the side surface 132 of the conductive lead 110.

Comparing the three examples of FIGS. 9-11, the pre-plated nickel-palladium-gold layer on the copper lead 910 in FIG. 9 in one example suffered a first board level reliability crack failure after 4569 temperature cycles, but this example suffers from the significant cost increase associated with pre-plated starting lead frame panel arrays. The post mold matte tin plating 1001 on the bottom of the lead 1010 in FIG. 10 provides significant cost reduction compared to the example of FIG. 9, but this example suffered the first board level reliability crack failure after only 2016 cycles.

The example implementation 1100 in FIG. 11 using the above-described first and second plated layers 111 and 112 provides cost benefits commensurate with the approach of FIG. 10, but exhibited significantly better BLR performance, having a first board level reliability crack occurrence after 5114 temperature cycles. The concepts of the present disclosure provide significant advantages with respect to manufacturing an electronic devices including cost savings as well as improved board level reliability without significant complexity in the manufacturing process. In certain implementations, the first and second plating processes 600 and 700 (e.g., FIGS. 6 and 7) can be incorporated into standard QFN or other no-lead packaging processes. The described examples provide a cost effective solution for automotive, industrial and other applications in which board level reliability is important.

In addition, the described examples allow the use of bare copper starting lead frames thereby reducing lead frame manufacturing time to market. Moreover, the nickel tungsten first plated layer 111 and matte tin second plated layer 112 provide board level reliability advantages in larger dimension packages as well as package designs having reduced lead pitch dimensions to support enhanced solderability and board level reliability performance in QFN and other package types and forms.

The described implementations can be used in a variety of applications including those that may be subjected to adverse environmental conditions while protecting against corrosion or degradation of the conductive metal of the lead bottom, and can be used alone or in conjunction with wettable flank options to provide a protective coating to surface mount device lead surfaces to mitigate corrosion and lengthen shelf-life of an electronic device prior to soldering onto a host printed circuit board (PCB). In addition, the described solutions can be used in combination with automated optical inspection (AOI) of devices soldered to a PCB for determining whether a proper connection has been made on a pad under the device.

The above examples are merely illustrative of several possible implementations of various aspects of the present disclosure, wherein equivalent alterations and/or modifications will occur to others skilled in the art upon reading and understanding this specification and the annexed drawings. Modifications are possible in the described examples, and other implementations are possible, within the scope of the claims.

What is claimed is:

1. An electronic device, comprising:
a package structure;
a conductive lead partially enclosed by the package structure, the conductive lead including copper;
a first plated layer on a portion of the conductive lead, the first plated layer including nickel tungsten; and
a second plated layer on the first plated layer, the second plated layer including tin, and the second plated layer exposed outside the package structure.

2. The electronic device of claim 1, wherein the first plated layer has a thickness that is 0.5 μm or more and 1.5 μm or less.

3. The electronic device of claim 2, wherein the thickness of the first plated layer is approximately 1.0 μm.

4. The electronic device of claim 2, wherein the second plated layer has a thickness that is 22.0 μm or less.

5. The electronic device of claim 2, wherein the second plated layer has a thickness that is 3.0 μm or more and 22.0 μm or less.

6. The electronic device of claim 2, wherein the second plated layer includes matte tin.

7. The electronic device of claim 1, wherein the second plated layer has a thickness that is 22.0 μm or less.

8. The electronic device of claim 1, wherein the second plated layer has a thickness that is 3.0 μm or more and 22.0 μm or less.

9. The electronic device of claim 1, wherein the second plated layer includes matte tin.

10. A system, comprising:
a circuit board having a conductive feature;
an electronic device, including a package structure, a conductive lead partially enclosed by the package structure and soldered to the conductive feature of the circuit board, the conductive lead including copper, a first plated layer on a portion of the conductive lead, the first plated layer including nickel tungsten, and a second plated layer on the first plated layer, the second plated layer including tin, and the second plated layer exposed outside the package structure; and
solder connecting the second plated layer to the conductive feature of the circuit board.

11. The system of claim 10, wherein the first plated layer has a thickness that is 0.5 μm or more and 1.5 μm or less.

12. The system of claim 11, wherein the second plated layer has a thickness that is 22.0 μm or less.

13. The system of claim 10, wherein the second plated layer has a thickness that is 3.0 μm or more and 22.0 μm or less.

14. The system of claim 10, wherein the second plated layer includes matte tin.

15. A method of fabricating an electronic device, the method of comprising:
performing a first plating process that forms a first plated layer including nickel tungsten on a first surface of a conductive lead exposed along a bottom side of a molded structure in a panel array of prospective electronic devices;
performing a second plating process that forms a second plated layer including tin on the first plated layer; and
performing a package separation process that separates an electronic device from the panel array, with the second plated layer exposed along the bottom side of a respective package structure and a second surface of the conductive lead exposed along a further side of the package structure.

16. The method of claim 15, wherein the first plating process forms the first plated layer to a thickness that is 0.5 μm or more and 1.5 μm or less.

17. The method of claim 16, wherein the second plating process forms the second plated layer to a thickness that is 22.0 μm or less.

18. The method of claim 16, wherein the second plating process forms the second plated layer to a thickness that is 3.0 μm or more and 22.0 μm or less.

19. The method of claim 15, wherein the second plating process forms the second plated layer to a thickness that is 22.0 μm or less.

20. The method of claim 15, wherein the second plating process forms the second plated layer to a thickness that is 3.0 μm or more and 22.0 μm or less.
